(19) United States
(12) Patent Application Publication
(10) Pub. No.: US 2024/0145630 A1
(43) Pub. Date: May 2, 2024

(54) LIGHT-EMITTING DEVICE AND METHOD FOR MANUFACTURING THE SAME

(71) Applicant: XIAMEN SAN’AN OPTOELECTRONICS CO., LTD., Xiamen (CN)

(72) Inventors: Minyou HE, Xiamen (CN); Xiaoliang LIU, Xiamen (CN); Qing WANG, Xiamen (CN); Ling-Yuan HONG, Xiamen (CN); Chung-Ying CHANG, Xiamen (CN)

(21) Appl. No.: 18/498,189

(22) Filed: Oct. 31, 2023

(30) Foreign Application Priority Data
Nov. 1, 2022 (CN) 202211355566.7

(51) Int. Cl. H01L 33/22; H01L 33/00

(52) U.S. Cl. CPC H01L 33/22; H01L 33/0095

(57) ABSTRACT

A light-emitting device includes a substrate and an epitaxial structure. The epitaxial structure includes a first semiconductor layer, an active layer, and a second semiconductor layer which are disposed on the upper surface of the substrate in such order. The substrate has a substrate edge region surrounding and exposed from the epitaxial structure. The substrate edge region includes a first substrate edge region and a second substrate edge region which is more proximate to the epitaxial structure than the first substrate edge region. The first substrate edge region has a first uneven toothed surface or an even flat surface. The second substrate edge regions are formed with second uneven toothed surfaces which have a height greater than a height of the first even toothed surface, or the even flat surface.

### CROSS-REFERENCE TO RELATED APPLICATION

This application claims priority to Chinese Invention Patent Application No. 202211355566.7, filed on Nov. 1, 2022, and incorporated by reference herein in its entirety.

### FIELD

The disclosure relates to a semiconductor device, and more particularly to a light-emitting device and a method for manufacturing the same.

### BACKGROUND

Light-emitting diode is a solid light-emitting device that converts electrical energy into light energy. For the light-emitting diode, the light emitting area is an important factor affecting the luminous brightness. In general, each wafer is one substrate for epitaxial growth. Referring to FIGS. 1a to 2c, in a conventional method for manufacturing a light-emitting diode, an N-type semiconductor layer 201, an active layer 202, and a P-type semiconductor layer 203 are successively formed on a wafer substrate 100 in such order, followed by etching the P-type semiconductor layer 203 and the active layer 202 from a surface of the P-type semiconductor layer 203 so as to expose a part of the N-type semiconductor layer 201, thereby forming a mesa structure. Subsequently, the wafer substrate 100 is ground to reduce the thickness thereof, and the exposed part of the N-type semiconductor layer 201 and a part of the wafer substrate 100 immediately beneath the exposed part of the N-type semiconductor layer 201 are diced to singulate LED chips. However, before dicing, the wafer substrate has a large surface area, and after the wafer substrate is thinned, the wafer substrate becomes thin; the N-type semiconductor layer 201 is a continuous layer which is thick. Therefore, the wafer substrate 100 can be subjected to a large stress and is prone to warpage and crack during dicing.

### SUMMARY

Therefore, an object of the disclosure is to provide a light-emitting device and method for manufacturing the same that can alleviate at least one of the drawbacks of the prior art.

According to one aspect of the disclosure, the method includes the steps of:
(a) providing a substrate having an upper surface which is patterned, and forming an epitaxial multilayer stack on the upper surface of the substrate, the epitaxial multilayer stack including a first semiconductor layer, an active layer, and a second semiconductor layer which are disposed on the upper surface of the substrate in such order;
(b) etching, from an upper surface of the second semiconductor layer, the second semiconductor layer and the active layer until the first semiconductor layer is exposed so as to form multiple mesa structures, each of which includes a mesa top defined by the upper surface of the second semiconductor layer, a mesa sidewall portion extending downwardly from the mesa top and formed by lateral edge portions of the second semiconductor layer and of the active layer, and a mesa bottom formed by an exposed part of the first semiconductor layer surrounding the mesa sidewall portion; and
(c) etching boundary regions of the mesa structures until the substrate is exposed so as to form dicing line regions on the substrate, each of the boundary regions of the mesa structures including a first boundary region formed by the mesa bottom, and a second boundary region that extends from the mesa top to a bottom surface of the first semiconductor layer and that includes the mesa sidewall portion, and a portion of the first semiconductor layer located beneath the mesa sidewall portion and adjoining the mesa bottom, the dicing line regions being formed after the first and second boundary regions of the mesa structures are etched and removed from the substrate.

According to another aspect of the disclosure, the light-emitting device includes a substrate and an epitaxial structure formed on an upper surface of the substrate. The epitaxial structure includes a first semiconductor layer, an active layer, and a second semiconductor layer which are disposed on the upper surface of the substrate in such order. The substrate has a substrate edge region surrounding and exposed from the epitaxial structure. The substrate edge region includes a first substrate edge region and a second substrate edge region which is more proximate to the epitaxial structure than the first substrate edge region. The first substrate edge region has a first uneven toothed surface or an even flat surface. The second substrate edge regions are formed with second uneven toothed surfaces which have a height greater than a height of the first even toothed surface, or the even flat surface.

According to yet another aspect of the disclosure, the light-emitting device includes a substrate and an epitaxial structure formed on an upper surface of the substrate. The epitaxial structure includes a first semiconductor layer, an active layer, and a second semiconductor layer which are disposed on the upper surface of the substrate in such order. The substrate has a substrate edge region surrounding and exposed from the epitaxial structure. The substrate edge region includes a first substrate edge region and a second substrate edge region which is more proximate to the epitaxial structure than the first substrate edge region. A thickness of the substrate in the first substrate edge region is smaller than a thickness of the substrate in the second substrate edge region.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1a is a schematic view illustrating a conventional method for manufacturing a light-emitting diode, in which an etching is performed to form mesa structures.

FIG. 1b is a schematic view illustrating a subsequent etching step of the conventional method for manufacturing a light-emitting diode to form a dicing line between the mesa structures.

FIG. 1c is a schematic view illustrating the conventional method for manufacturing a light-emitting diode, in which the light-emitting diode is singulated after dicing.

FIG. 2a is a schematic view illustrating an initial step of the conventional method for manufacturing a light-emitting diode to form an epitaxial multilayer stack on a substrate.

FIG. 2b is the same view as FIG. 1b, but showing a dicing line different from that shown in FIG. 1b.

FIG. 2c is a schematic view illustrating the conventional method for manufacturing a light-emitting diode, in which the light-emitting diode is singulated after the dicing step of FIG. 2b.

FIG. 3a is a schematic view illustrating a method for manufacturing a light-emitting diode according to a first embodiment of the present disclosure, in which an epitaxial multilayer stack is formed on a substrate.

FIG. 3b is a schematic view illustrating the method for manufacturing a light-emitting diode of the first embodiment, in which multiple mesa structures are formed after etching an epitaxial multilayer stack grown on a substrate.

FIG. 3c is a schematic view illustrating the step of etching boundary regions of the mesa structures in the method so as to form dicing line regions on an exposed part of the substrate.

FIG. 3d is the same view as FIG. 3c, but showing a flat even exposed part of the substrate beneath the dicing line region.

FIG. 4a is a schematic sectional view illustrating a light-emitting device according to a second embodiment of the present disclosure.

FIG. 4b is a schematic sectional view illustrating a variation of the light-emitting device according to the second embodiment of the present disclosure.

FIG. 5a is a schematic sectional view illustrating a light-emitting device according to a third embodiment of the present disclosure.

FIG. 5b is a schematic top view showing the light-emitting device illustrated in FIG. 5a.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

### First Embodiment

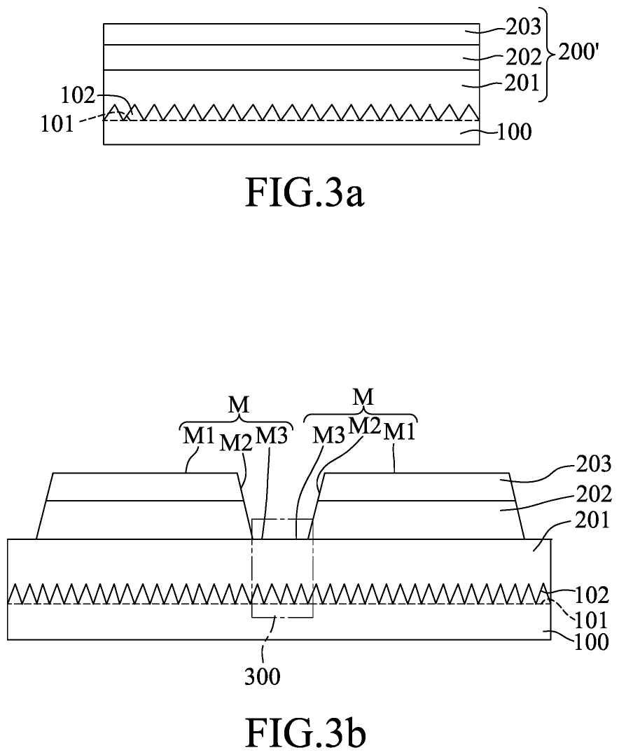

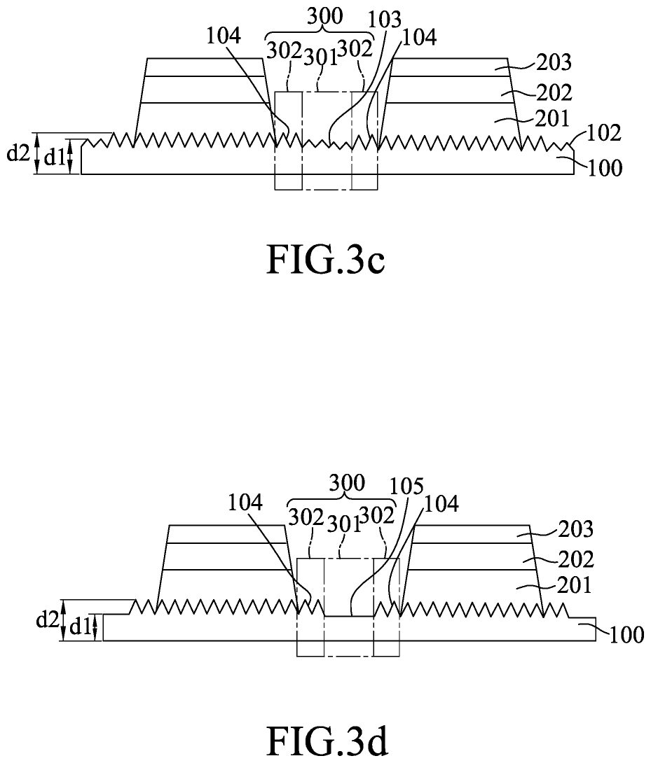

Referring to FIGS. 3a to 3d, a method for manufacturing a light-emitting device according to the present disclosure is shown; the method includes following steps S101 to S104.

In step S101, as shown in FIG. 3a, a substrate 100 having an upper surface which is patterned is provided, and an epitaxial multilayer stack 200′ is formed on the upper surface of the substrate 100. The substrate 100 may be a sapphire substrate, and has an upper surface and a lower surface opposite to the upper surface. The pattern formed on the upper surface of the substrate may be made of aluminum oxide, has a height ranging from 1.5 μm to 3 μm, and has a width ranging from 2 μm to 4 μm. The epitaxial multilayer stack 200′ includes a first semiconductor layer 201, an active layer 202, and a second semiconductor layer 203 which are disposed on the upper surface of the substrate 100 in such order. The first semiconductor layer 201 may be an n-type semiconductor layer, the active layer 202 may be a quantum well layer, and the second semiconductor layer 203 may be a p-type semiconductor layer. The first semiconductor layer 201, the active layer 202, and the second semiconductor layer 203 may be made of GaN-based materials, and may be formed by deposition.

In this embodiment, after the epitaxial multilayer stack 200′ is formed on the substrate 100, a conductive layer (not shown) is formed on a surface of the second semiconductor layer 203. The conductive layer may be made of indium tin oxide, nickel gold, or the like, and may be etched in a subsequent step.

In step S102, as shown in FIG. 3b, the second semiconductor layer 203 and the active layer 202 are etched from an upper surface of the second semiconductor layer 203 until the first semiconductor layer 201 is exposed so as to form multiple mesa structures (M). Each of the mesa structures (M) includes a mesa top (M1) which is defined by the upper surface of the second semiconductor layer 203, a mesa sidewall portion (M2) which extends downwardly from the mesa top (M1) and is formed by lateral edge portions of the second semiconductor layer 203 and of the active layer 202, and a mesa bottom (M3) which is formed by an exposed part of the first semiconductor layer 201 and which loops around the mesa sidewall portion (M2). The mesa bottom (M3) is flush with a lower surface of the active layer 202 or lower than the lower surface of the active layer 202.

Referring to FIG. 3b, in particular, after a part of the conductive layer (not shown) is etched to expose a part of the upper surface of the second semiconductor layer 203, the second semiconductor layer 203 and the active layer 202 are successively etched from the exposed part of the upper surface of the second semiconductor layer 203, until the upper surface of the first semiconductor layer 201 is exposed, thereby forming multiple mesa structures (M). The exposed upper surface of the first semiconductor layer 201 forms the mesa bottoms (M3) each of which is formed at a boundary region of each of the mesa structures (M). In some embodiments, besides the mesa bottoms (M3) located at the boundary region of each mesa structure (M), the exposed upper surface of the first semiconductor layer 201 also forms internal mesas (not shown) located within an area surrounded by the boundary region of each mesa structure (M). N type electrodes may be formed on the mesa bottom (M3). In an example, one or more N type electrodes are formed on a part of the mesa bottom (M3). In another example, one or more N type electrodes are formed at the internal mesas (not shown), and no electrode is formed at the mesa bottom (M3).

In step S103, as shown in FIGS. 3b to 3d, boundary regions of the mesa structures (M) are etched until the substrate 100 is exposed so as to form dicing line regions 300 (only one is shown) on the substrate 100, each of which is formed between two adjacent ones of the mesa structures (M). Each of the boundary regions of the mesa structures (M) includes a first boundary region which is formed by the mesa bottom (M3), and a second boundary region which extends from the mesa top (M1) to a bottom surface of the first semiconductor layer 201 and which includes the mesa sidewall portion (M2) and a portion of the first semiconductor layer 201 located beneath the mesa sidewall portion (M2) and adjoining the mesa bottom (M3). The dicing line regions 300 are formed after the first and second boundary regions of the mesa structure (M) are etched and removed from the substrate 100. Each of the dicing line regions 300 has a width greater than a width of the mesa bottom (M3).

In this embodiment, the etching in step S103 is inductively coupled plasma (ICP) etching, where an ICP etching gas is used for etching the mesa structure (M).

Referring to FIGS. 3b to 3d, in this embodiments, the first and second boundary regions of the mesa structure (M) are simultaneously etched and removed until the substrate 100 is exposed, such that the dicing line region 300 has a width greater than a width of the mesa bottom (M3). Each of the dicing line regions 300 is situated between two adjacent ones of the mesa structures (M), and includes a first dicing line region 301, and two second dicing line regions 302 on two opposite sides of the first dicing line region 301. The first dicing line region 301 is formed on an exposed part of the substrate 100 from which the first boundary regions of two adjacent ones of the mesa structures (M) are removed, and the second dicing line regions 302 are respectively formed on other exposed parts of the substrate 100 from which the second boundary regions of two adjacent ones of the mesa structures (M) are removed. As shown in FIGS. 3c and 3d, the other exposed parts of the substrate 100 where the second dicing line regions 302 are formed has a thickness (d2) greater than a thickness (d1) of the exposed part of the substrate 100 where the first dicing line region 301 is formed. It is noticed that, since the substrate 100 may has uneven toothed surfaces 103, 104 which will be described below, the above-stated thicknesses (D1, D2) of the substrate 100 are distances between the lower surface the substrate 100 and tops of the uneven toothed surfaces 103, 104, respectively. For each of the mesa structures (M), since the thickness of the first boundary region is lower than the thickness of each second boundary region, after etching of the first boundary region is completed, the ICP etching gas still continues its etching activity until the second boundary regions are cleared from the substrate 100, and stops etching at the upper surface of the substrate 100.

Referring to FIGS. 3a and 3b, in this embodiment, the substrate 100 is a patterned substrate, and includes a flat base layer 101 and an uneven toothed structure layer 102 which is formed on an even surface of the flat base layer 101 and which includes a plurality of protrusions spaced apart from each other. The mesa structures (M) are formed on a surface of the uneven toothed structure layer 102 of the substrate 100.

Referring to FIG. 3c, in an example of the embodiment, in step S103, the first and second boundary regions of the mesa structures (M) are simultaneously etched such that an exposed part of the substrate 100 from which the first boundary regions of two adjacent ones of the mesa structures (M) are removed is formed with a first uneven toothed surface 103, and other exposed parts of the substrate 100, from which the second boundary regions of two adjacent ones of the mesa structures (M) are removed, are respectively formed with second uneven toothed surfaces 104. The first and second uneven toothed surfaces 103, 104 are formed after etching is performed at the surface of the uneven toothed structure layer 102. The exposed part of the substrate 100 where the first uneven toothed surface 103 is formed has the first dicing line region 301 thereon, and the other exposed parts of the substrate 100 where the second uneven toothed surfaces 104 are formed have the second dicing line regions 302 thereon. The first uneven toothed surface 103 has a height lower than a height of the second uneven toothed surfaces 104. In particular, for each of the mesa structures (M), the first boundary region is etched from the mesa bottom (M3); the etching of the second boundary region starts from the mesa top (M1) and is conducted simultaneously with the etching of the first boundary region, so that the height of the first uneven toothed surface 103 formed in the first dicing line region 301 is lower than the height of the second uneven toothed surfaces 104. In some embodiments, the second uneven toothed surfaces 104 of the substrate 100 may be formed to have a height lower than an original height of the uneven toothed structure layer 102.

Referring to FIG. 3d, in another example of the embodiment, in step S103, the first boundary region and the second boundary regions of the mesa structures (M) are simultaneously etched until the substrate 100 is exposed, and each of the dicing line regions 300 is situated between two adjacent ones of the mesa structures (M), and includes a first dicing line region 301, and two second dicing line regions 302 on two opposite sides of the first dicing line region 301. An exposed part of the substrate 100, from which the first boundary regions of two adjacent ones of the mesa structures (M) are removed, has an even flat surface 105 on which the first dicing line region 301 is formed, and other exposed parts of the substrate 100 from which the second boundary regions of two adjacent ones of the mesa structures (M) are removed have uneven toothed surfaces 104. Each of the other exposed parts of the substrate 100 having a second dicing line region 302 formed thereon. The even flat surface 105 of the substrate 100 may be the even surface of the flat base layer 101 of the substrate 100, or may be a surface of the substrate 100 which is exposed as a result of etching the even surface of the flat base layer 101 of the substrate 100 in certain degree. The uneven toothed surfaces 104 of the substrate 100 may be formed to have a height equal to the original height of the uneven toothed structure layer 102, or may be formed to have a height lower than the original height of the uneven toothed structure layer 102.

In some embodiments, for each mesa structure (M), the width of the mesa bottom (M3) is in a range from 2 μm to 38 μm, and the width of the dicing line region 300 formed after removal of the mesa bottom (M3) is in a range from 4 μm to 40 μm.

In some embodiments, for each mesa structure (M), the width of the first dicing line region 301 is in a range from 2 μm to 38 μm, and the width of the second dicing line region 302 is in a range from 2 μm to 38 μm. The width of the first dicing line region 301 may be less than the width of the second dicing line region 302. Alternatively, the width of the first dicing line region 301 may be equal to or greater than the width of the second dicing line region 302.

In some embodiments, the height of the first uneven toothed surface 103 is not greater than 2 μm. Further, the height of the first uneven toothed surface 103 may be in a range from 1 μm to 2 μm or may be less than 1 μm. In some embodiments, the height of the second uneven toothed surface 104 is not greater than 2 μm. Further, the height of the second uneven toothed surface 104 may be in a range from 1 μm to 2 μm or may be less than 1 μm.

According to this embodiment, the part of the substrate where the first dicing line region 301 is formed has a relatively even surface in comparison with the other parts of the substrate 100 where the second dicing regions 302 are formed, and the other parts of the substrate 100 where the second dicing regions 302 are formed may have a relatively even surface in comparison with a part of the substrate 100 where the mesa structures (M) remain thereon. Therefore, when an insulation layer is formed on the second dicing line region 302, the insulation layer can be bonded more tightly on the substrate 100, so as to improve production yield of the light-emitting device.

According to this embodiment, since there is a difference between the thickness of the parts of the substrate 100 where the second dicing line regions 302 are formed and the thickness of the exposed part of the substrate 100 where the first dicing line region 301 is formed, a part of the first semiconductor layer 201 which corresponds in position to the first dicing line region 301 can be completely etched, so that a current leakage which may be caused due to incomplete etching of the part of the first semiconductor layer 201 can be prevented, thereby improving the luminous efficiency of the light-emitting device.

In step S104, parts of the substrate 100 each located immediately beneath the dicing line regions 300 are subjected to stealth dicing from the lower surface of the substrate 100 so as to form modified points inside the substrate 100, and an external force is applied to the substrate 100 to cut the substrate 100 along the dicing line regions 300, thereby obtaining singulated light-emitting devices each of which includes the substrate 100 and the mesa structure (M) formed on the substrate 100.

### Second Embodiment

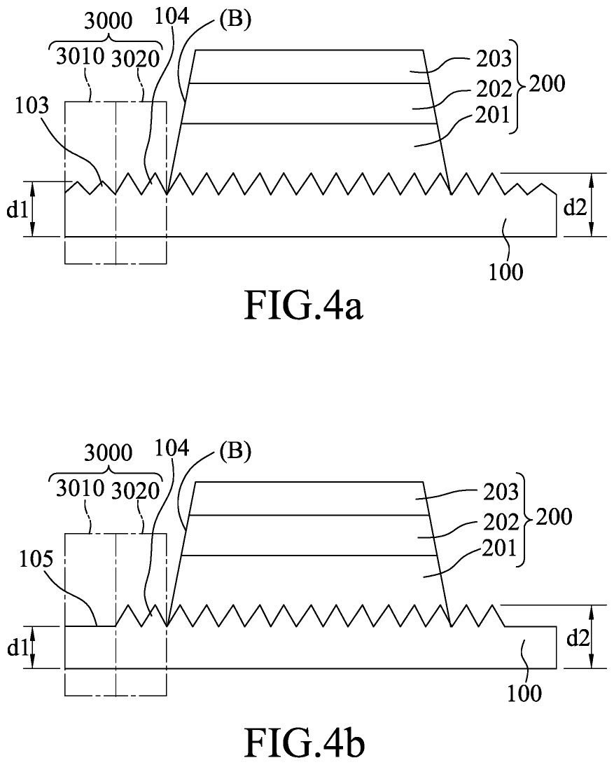

Referring to FIG. 4a, a light-emitting device according to the present disclosure is shown, which is manufactured by the method of First Embodiment.

The light-emitting device includes a substrate 100 and an epitaxial structure 200 formed on an upper surface of the substrate 100. The epitaxial structure 200 includes a first semiconductor layer 201, an active layer 202, and a second semiconductor layer 203 which are disposed on the upper surface of the substrate 100 in such order. The substrate 100 has a substrate edge region 3000 surrounding and exposed from the epitaxial structure 200. The substrate edge region 3000 includes a first substrate edge region 3010 and a second substrate edge region 3020 which is proximate to the epitaxial structure 200 than the first substrate edge region 3010. The first substrate edge region 3010 has a first uneven toothed surface 103, and the second substrate edge region 3020 has a second uneven toothed surface 104 which has a height greater than a height of the first uneven toothed surface 103. Accordingly, the first substrate edge region 3010 (here, the edge region 3010 refers to an edge part or portion of the substrate 100) has a thickness (d1) less than a thickness (d2) of the second substrate edge region 3020.

Referring to FIG. 4b, a variation of the second embodiment of the light-emitting device is shown. In this variation, unlike the first substrate edge region 3010 shown in FIG. 4a, the first substrate edge region 3010 has an even flat surface 105. Specifically, in this variation, the first substrate edge region 3010 has an even flat surface 105, and the second substrate edge region 3020 has a second uneven toothed surface 104. The flat even surface 105 is flat and has no protrusion. Accordingly, the first substrate edge region 3010 has a thickness (d1) less than a thickness (d2) of the second substrate edge region 3020.

In some embodiments, each of the first and second uneven toothed surfaces 103, 104 includes a plurality of protrusions which have a pointed cone-shape, and each of the protrusions of the first uneven toothed surface 103 or the second uneven toothed surface 104 has an arcuate side wall. The arcuate side wall may be concave or convex.

In some embodiments, the epitaxial structure 200 has a boundary sidewall (B) which extends downward continuously from the second semiconductor layer 203 and has a bottom end meeting an upper surface of the substrate edge region 3000, and no step is formed on at least a portion of the boundary sidewall (B) of the epitaxial structure 200.

In some embodiments, the epitaxial structure 200 has a boundary sidewall (B) which extends downward continuously from the second semiconductor layer 203 and has a bottom end meeting the substrate edge region 3000, and no step is formed on all part of the boundary sidewall (B) of the epitaxial structure 200. In such embodiments, the second substrate edge region 3020 surrounds the epitaxial structure 200, and the first substrate edge region 3010 surrounds the second substrate edge region 3020.

In some embodiments, the epitaxial structure 200 has a boundary side wall (B) which includes a portion extending downward continuously from the second semiconductor layer 203 and has a bottom end meeting the substrate edge region 3000, and no step is formed on the portion of the boundary sidewall (B) of the epitaxial structure 200 while a step is formed on a remaining portion of the boundary sidewall (B) of the epitaxial structure 200 other than the portion of the boundary sidewall (B). The step is provided for forming an electrode.

In some embodiments, the substrate edge region 3000 of the substrate 100 has a width ranging from 2 μm to 20 μm, such as from 6 μm to 15 μm, or from 8 μm to 12 μm.

In some embodiments, the first substrate edge region 3010 has a width ranging from 1 μm to 19 μm, such as from 3 um to 10 μm, from 4 um to 8 μm, or 6 um, and the second substrate edge region 3020 has a width ranging from 1 μm to 19 μm, such as from 3 um to 10 μm, from 4 um to 8 μm, or 6 um.

The width of the first substrate edge region 3010 may be less than the width of the second substrate edge region 3020. Alternatively, the width of the first substrate edge region 3010 may be equal to or greater than the width of the second substrate edge region 3020.

The first substrate edge region 3010 may have an area which is as large as possible. For example, the width of the first substrate edge region 3010 is greater than the width of the second substrate edge region 3020, so as to allow the pattern of the substrate edge region 3000 to have a relatively low height, which is beneficial to coverage of an insulation layer on the epitaxial structure 200 and the first and second substrate edge regions 3010, 3020.

### Third Embodiment

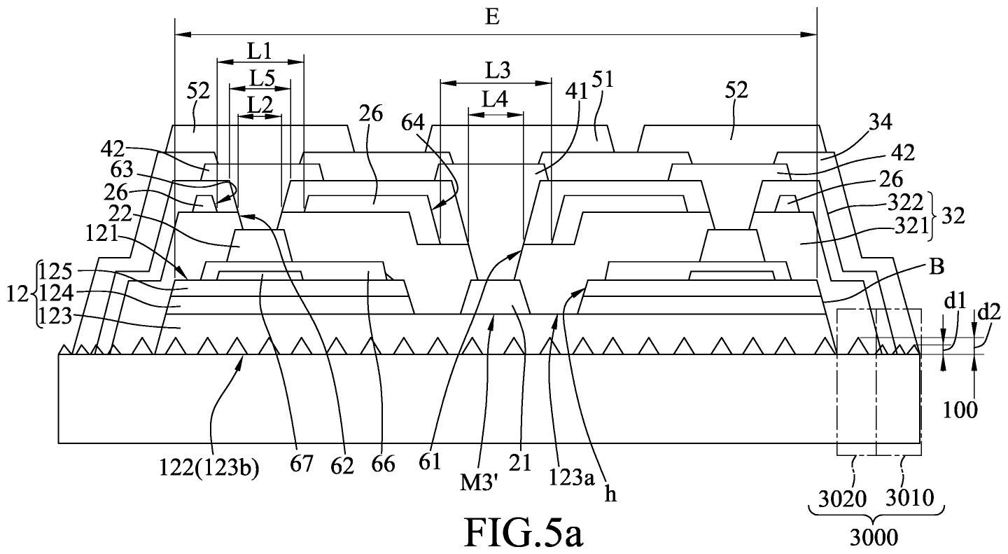

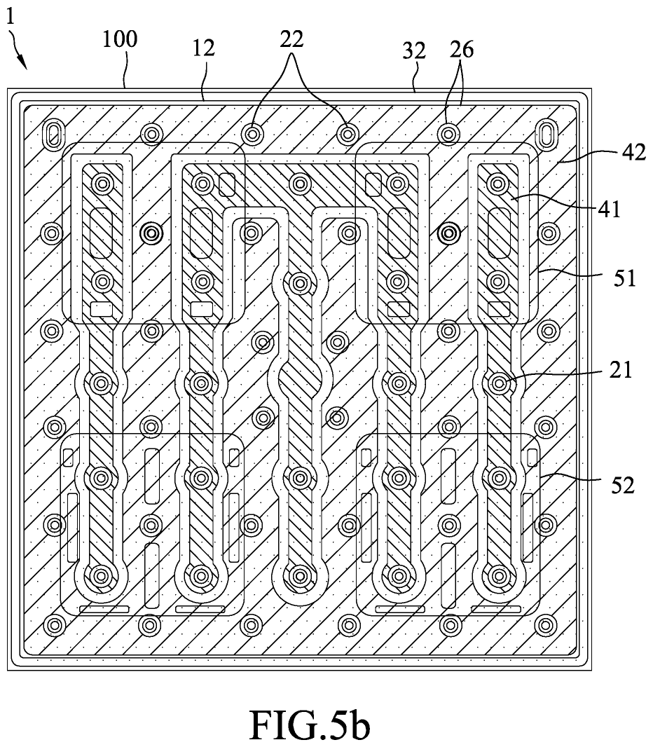

FIGS. 5a and 5b show a flip-chip type light-emitting device 1 which is also produced by the method of the first embodiment. The light-emitting device 1 includes an epitaxial structure 12 which may be the same structure as the epitaxial structure 200 shown in FIG. 4a. The epitaxial structure 12 includes a first semiconductor layer 123, an active layer 124, and a second semiconductor layer 125.

Specifically, as shown in FIG. 5a, the epitaxial structure 12 has an upper surface 121 and a lower surface 122 opposite to the upper surface 121. Further, the epitaxial structure 12 includes the first semiconductor layer 123, the active layer 124, and the second semiconductor layer 125 which are disposed on a substrate 100 in such order from the lower surface 122 to the upper surface 121. That is to say, the active layer 124 is located between the first semiconductor layer 123 and the second semiconductor layer 125. The first semiconductor layer 123 has an upper surface 123a where the active layer 124 is formed thereon, and a lower surface 123b (i.e., the lower surface 122 of the epitaxial structure 12) which faces toward the substrate 100. The first semiconductor layer 123 may be an N-type semiconductor layer. The substrate 100 includes a substrate edge region 3000 which is the same as the substrate edge region 3000 of the second embodiment shown in FIG. 4a.

As shown in FIG. 5a, parts of the upper surface 121 of the epitaxial structure 12 are exposed from the active layer 124, and the exposed parts of the first semiconductor layer 123 define multiple internal mesa bottoms (M3′) (only one is shown in FIG. 5a for the sake of brevity). The internal mesa bottoms (M3′) are located within an internal area (E) of the epitaxial structure 12, and a boundary sidewall (B) of the epitaxial structure 12 loops around the internal area (E); a plurality of through holes (h) (only one is shown in FIG. 5a) are formed in the internal area (E) above the internal mesa bottoms (M3′), respectively. The substrate edge region 3000 of the substrate 100 loops around the boundary sidewall (B) of the epitaxial structure 12 and is exposed from the epitaxial structure 12. The substrate edge region 3000 includes a first substrate edge region 3010 and a second substrate edge region 3020 which is more proximate to the boundary sidewall (B) of the epitaxial structure 12 than the first substrate edge region 3010. The first substrate edge region 3010 has a thickness (d1) less than a thickness (d2) of the second substrate edge region 3020. In addition, the light-emitting device 1 may further includes an insulation layer 32 which covers the epitaxial structure 12 and the first and second substrate edge regions 3010, 3020 of the substrate edge region 3000. Since the first substrate edge region 3010 is lower than the second substrate edge region 3020, the insulation layer 32 can efficiently enclose the second substrate edge region 3020, and a current leakage which may be caused due to incomplete etching of the first semiconductor layer 123 on the second substrate edge region 3020 can be prevented, thereby improving the manufacturing yield of the light-emitting device.

In this embodiment, the epitaxial structure 12 has the boundary sidewall (B) which extends downward continuously from the second semiconductor layer 125 and has a bottom end meeting the upper surface of the substrate edge region 3000, and no step is formed on all part of the boundary sidewall (B) of the epitaxial structure 12. The second substrate edge region 3020 surrounds the epitaxial structure 12, and the first substrate edge region 3010 surrounds the second substrate edge region 3020.

In this embodiment, the boundary sidewall (B) of the epitaxial structure 12 is not formed with any step; specifically, the boundary sidewall (B) has no mesa bottom formed by the first semiconductor layer 123, which can affect the light emitting area of the light-emitting device 1, thereby improving the light emitting efficiency of the light-emitting device 1. Accordingly, since the light emitting area of the light-emitting device 1 is not affected, and since a metal reflection layer 26 is formed as described below, the brightness of the light-emitting device 1 can be significantly improved.

In this embodiment, the light-emitting device 1 further includes a first metal electrode 21 and a second metal electrode 22. The first metal electrode 21 is located above the upper surface 121 of the epitaxial structure 12, and is electrically connected to the first semiconductor layer 123. In some embodiments, the first metal electrode 21 is directly formed on the mesa bottom formed by the first semiconductor layer 123, so as to ensure a good ohmic contact between the first metal electrode 21 and the first semiconductor layer 123.

The second metal electrode 22 is located above the upper surface 121 of the epitaxial structure 12 (i.e., the upper surface of the second semiconductor layer 125), and is electrically connected to the second semiconductor layer 125. The second metal electrode 22 may be made of the same material as that of the first metal electrode 21. FIG. 5b which is a top view shows a more detailed configuration of the internal area (E) of the light-emitting device 1. As shown in FIG. 5b, each of the first and second metal electrodes 21, 22 has a circular or elliptical shape. Each of the first and second metal electrodes 21, 22 may have a width ranging from 5 μm to 50 μm, such as 10 μm, 20 μm, 30 μm.

In this embodiment, the light-emitting device 1 further includes a first connection electrode 41 and a second connection electrode 42. The insulation layer 32 partially covers the epitaxial structure 12, the first metal electrodes 21, and the second metal electrodes 22. The insulation layer 32 includes a first insulation layer 321 and a second insulation layer 322. The second insulation layer 322 is located above the first insulation layer 321. The insulation layer 32 has first holes 61 and second holes 62. Each of the first holes 61 is located above one of the first metal electrodes 21, so that, through each of the first holes 61, the first connection electrode 41 is electrically connected to the first metal electrode 21. Each of the second holes 62 is located above one of the second metal electrodes 22, so that, through each of the second holes 62, the second connection electrode 42 is electrically connected to the second metal electrode 22. Both of the first holes 61 and the second holes 62 extend through the first and second insulation layers 321, 322. The insulation layer 32 has different effects depending on the positions thereof. For example, when the insulation layer 32 covers the boundary sidewall (B) of the epitaxial structure 12, it may prevent the first and second semiconductor layers 123, 125 from being electrically connected to each other by leaked conductive materials, so as to prevent short circuit of the light-emitting device 1. The insulation layer 32 includes a non-conductive material, such as silicon dioxide, silicon nitride, titanium oxide, tantalum oxide, niobium oxide, barium titanate, and a combination thereof; the combination may form a Bragg reflector (DBR).

In some embodiments, the first insulation layer 321 is an insulating reflective layer formed by repeatedly stacking two insulating materials. In an example where the first insulation layer 321 is a DBR layer, the optical thickness of each sub-layer of the DBR layer is about 137.5 nm, and the DBR layer has a thickness ranging from 2 μm to 6 μm, and includes 10 to 30 pairs of the sub-layers. In some embodiments, in order to ensure reflectance of the DBR layer, the DBR layer includes 20 to 30 pairs of the sub-layers, has a thickness ranging from 4 to 6 μm. In some embodiments, the DBR layer includes 22 pairs of the sub-layers, and has a thickness of 5 μm.

A part of or all of the insulation layer 32 covers all of the substrate edge region 3000 of the substrate 100.

In this embodiment, the light-emitting device 1 further includes a metal reflection layer 26 formed between the first insulation layer 321 and the second insulation layer 322 of the insulation layer 32. The metal reflection layer 26 is used to reflect light so that more light can be emitted from a light emitting surface of the light-emitting device 1. In some embodiments, the metal reflection layer 26 includes Ag or Al.

The first connection electrode 41 is located above the insulation layer 32, and is connected to the first metal electrodes 21. The first connection electrode 41 is capable of spreading current, protects the first metal electrodes 21 located therebelow, and has functions of supporting and height adjustment. The material of the first connection electrode 41 may be selected from Cr, Pt, Au, Ni, Ti, Al, and combination thereof. In some embodiments, the first connection electrode 41 has a metal base layer which made of Ti or Cr, so as to facilitate adhesion between the first connection electrode 41 and the insulation layer 32. The second connection electrode 42 is located above the insulation layer 32, and is connected to the second metal electrodes 22. The second connection electrode 42 is capable of spreading current. The material of the second connection electrode 42 may be selected from Cr, Pt, Au, Ni, Ti, Al, and combination thereof. In some embodiments, the second connection electrodes 42 has a metal surface layer which is made of Ti or Cr, so as to facilitate adhesion between the second connection electrode 42 and the adjacent structure layers.

In some embodiments, each of the first and second holes 61,62 of the insulation layer 32 has a bottom width and a top width, and the bottom width of each of the first and second holes 61,62 is smaller than the top width of each of the first and second holes 61,62. This facilitates filling of the first and second connection electrodes 41, 42 into the first and second holes 61, 62 and allows the first and second connection electrodes 41, 42 to be formed continuously in the first and second holes 61, 62. In some embodiments, the top width of each first hole 61 is greater than the width of the upper surface of the first metal electrode 21, and the top width of each second hole 62 is greater than the width of the upper surface of the second metal electrode 22.

The first connection electrode 41 may be formed as a stripe or multiple stripes, or may be formed into a comb-shape; the second connection electrode 42 may be formed as a block. As shown in FIG. 5b, when the first and second connection electrodes 41, 42 are projected perpendicularly onto a common horizontal plane and are viewed from above the epitaxial structure 12, an area of the first connection electrode 41 is smaller than that of the second connection electrode 42, and the second connection electrode 42 generally surrounds the first connection electrode(s) 41.

The vertical projections of the first metal electrodes 21 and/or the second metal electrodes 22 on an imaginary common horizontal plane do not overlap with the vertical projection of the metal reflection layer 26 on the imaginary horizontal plane. That is to say, when viewing the epitaxial structure 12 from above of the light-emitting device 1, the first metal electrodes 21 and/or the second metal electrodes 22 do not intersect with or overlap with the metal reflection layer 26, such that none of the first and second metal electrodes 21, 22 are located within the vertical projection area of the metal reflection layer 26. If the vertical projections of the first metal electrodes 21 and/or the second metal electrodes 22 on the imaginary horizontal plane overlap with the vertical projection of the metal reflection layer 26 on the imaginary horizontal plane, the first holes 61 and/or the second holes 62 at the insulation layer 32 may be too small, and the metal reflection layer 26 may cover the first and second metal electrodes 21, 22. In such case, the insulation layer 32 located below the metal reflection layer 26 may cover the first and second metal electrodes 21, 22, so that steps may be formed. If the steps are formed, due to the brittleness of the insulation layer 32, the insulation layer 32 may be prone to crack at locations where the steps are formed, and a moisture may get into the light-emitting device 1 through the cracks formed in the insulation layer 32. Thus, the metal reflection layer 26 tends to migrate, so that the stability of reflectivity of the metal reflection layer 26 may be affected, and the metal reflection layer 26 may contact with a contact electrode disposed therebelow. This may cause a melt blending of the materials of the metal reflection layer 26, which may affect the stability of the metal reflection layer 26, and may cause the metal reflection layer 26 to be easily damaged in a subsequent process such as an etching process.

In some embodiments, the vertical projection of the lower surface of the first metal electrode 21 and/or the lower surface of the second metal electrode 22 on the imaginary horizontal plane do not overlap with the vertical projection of a lower surface of the metal reflection layer 26 on the imaginary horizontal plane. In some embodiments, the imaginary horizontal plane is a plane on which the lower surface 122 of the first semiconductor layer 123 of the epitaxial structure 12 shown in FIG. 5a is located.

In some embodiments, the metal reflection layer 26 has a thickness ranging from 200 nm to 1000 nm, such as from 300 nm to 600 nm. For example, the thickness of the metal reflection layer 26 may be 400 nm or 500 nm. The second insulation layer 322 has a thickness ranging from 200 nm to 1000 nm, such as from 200 nm to 400 nm, or from 400 nm to 600 nm.

In some embodiments, the metal reflection layer 26 is disposed above the upper surface 121 of the epitaxial structure 12, and is not disposed above the exposed part of the substrate 100 which is exposed from the epitaxial structure 12, so that the metal reflection layer 26 can be as flat as possible. In some embodiments, the metal reflection layer 26 is only disposed immediately above an upper surface of the second semiconductor layer 125, so that the metal reflection layer 26 thus formed can be as flat as possible and is prevented from being formed with a step or a height difference, thereby avoiding moisture erosion or metal migration problems and ensuring the stability of the metal reflection layer 26.

In some embodiments, the vertical projection of the metal reflection layer 26 on the upper surface of the second semiconductor layer 125 overlaps with the vertical projections of the first connection electrode 41 and the second connection electrode 42 on the upper surface of the second semiconductor layer 125. The vertical projection of the metal reflection layer 26 on the imaginary horizontal plane overlaps with the vertical projections of the first connection electrode 41 and the second connection electrode 42 on the imaginary horizontal plane.

In some embodiments, the area of the vertical projection of the metal reflection layer 26 on the upper surface of the second semiconductor layer 125 occupies at least 80% of the total area of the upper surface of the second semiconductor layer 125; the total area of the vertical projections of the second metal electrodes 22 on the upper surface of the second semiconductor layer 125 occupies less than 20% of the total area of the upper surface of the second semiconductor layer 125. In some embodiments, the light-emitting device 1 further includes a current blocking layer 67 which is disposed below the second metal electrode 22, and the area of the vertical projection of the current blocking layer 67 on the upper surface of the second semiconductor layer 125 occupies less than 20% of the total area of the upper surface of the second semiconductor layer 125.

In some embodiments, the second insulation layer 322 covers an upper surface and a sidewall of the metal reflection layer 26. Moreover, a part of the first insulation layer 321 and a part of the second insulation layer 322 which are located around the metal reflection layer 26 are in direct contact, so that the first insulation layer 321 and the second insulation layer 322 tightly sandwich the metal reflection layer 26, thereby improving the overall structural stability.

In some embodiments, as shown in FIG. 5a, the metal reflection layer 26 has a third hole 63 which is located above and communicates with the second hole 62, and a dimension L1 of the third hole 63 which is measured at a bottom part thereof is greater than a dimension L2 of the second hole 62 which is measured at a top part thereof (i.e., at a point where the first insulation layer 321 and the second insulation layer 322 are in contact with each other). Therefore, the metal reflection layer 26 thus formed can be as flat as possible, so that moisture erosion and metal migration which may be caused when a step or a height difference is formed on the metal reflection layer 26 can be avoided.

In some embodiments, as shown in FIG. 5a, the metal reflection layer 26 further has a fourth hole 64 which is located above and communicates with the first hole 61, and a dimension L3 of the fourth hole 64 which is measured at a bottom part thereof is greater than a dimension L4 of the first hole 61 which is measured at a top part thereof (i.e., at the point where the first insulation layer 321 and the second insulation layer 322 are in contact with each other.

In some embodiments, the dimension L1 of the third hole 63 is greater than a dimension L5 of the second hole 62 which is measured at a top part thereof, so as to ensure that the metal reflection layer 26 can be protected, thereby preventing the metal reflection layer 26 from being exposed or etched and damaged. The difference between the dimensions L1 and L5 may be at least 6 μm.

Each of the dimensions L1 to L5 may be a diameter or a width of each of the holes.

In one embodiment, as shown in FIG. 5a, the top part of the first hole 61 is higher than the upper surface of the first metal electrode 21, and the top part of the second hole 62 is higher than the upper surface of the second metal electrode 22. The heights of the first and second holes 61, 62 are determined based on the lower surface 122 of the first semiconductor layer 121 (i.e., the lower surface of the epitaxial structure 12) as a reference surface.

In the embodiment, the metal reflection layer 26 is formed flatly on the first insulation layer 321. Furthermore, the metal reflection layer 26 has edge parts with inclined edge faces which interconnect between upper and lower surfaces of the metal reflection layer 26. In such example, the second insulation layer 322 may have a thickness ranging from 200 nm to 1000 nm, and the inclined edge faces of the metal reflection layer 26 may have an inclination angle not greater than 40°, such as not greater than 30°, or not greater than 20°.

In some embodiments, as shown in FIG. 5a, the light-emitting device 1 further include an insulating structure 34, a first pad electrode 51, and a second pad electrode 52. The insulating structure 34 partially covers the insulation layer 32, the first connection electrode 41, and the second connection electrode 42, for mainly providing insulating protection function. The first pad electrode 51 is located above the insulating structure 34, and is connected to the first connection electrode 41. The second pad electrode 52 is located above the insulating structure 34, and is connected to the second connection electrode 42. The first and second pad electrodes 51, 52 may be metal pads.

In some embodiments, in addition to the current blocking layer 67, the light-emitting device 1 further include a transparent current spreading layer 66. The current blocking layer 67 is disposed between the second semiconductor layer 125 and the second metal electrode 22, and is capable of blocking a current. The transparent current spreading layer 66 is disposed between the current blocking layer 64 and the second metal electrode 22, covers the current blocking layer 67, and is capable of spreading a current. In some embodiments, the vertical projection of the metal reflection layer 26 on the imaginary horizontal plane does not overlap with the vertical projection of the current blocking layer 67 on the imaginary horizontal plane. The current blocking layer 67 may include silicon oxide, and has a width greater than that of the second metal electrode 22. Particularly, the bottom width of the current blocking layer 67 is greater than the bottom width of the second metal electrode 22, and the difference therebetween may be 2 μm to 6 μm. In some embodiments, in order to keep the metal reflection layer 26 away from the current blocking layer 67, the difference between the dimension L1 and the dimension L5 is at least 15 μm.

The transparent current spreading layer 66 is made of a transparent conductive material, such as, but not limited to, indium tin oxide (ITO).

In some specific embodiments, the metal reflection layer 26 is formed such that the vertical projection thereof on the imaginary horizontal plane falls within the vertical projection of the second semiconductor layer 125 on the imaginary horizontal plane. In other words, the metal reflection layer 26 is only disposed immediately above the second semiconductor layer 125, so that the metal reflection layer 26 thus formed can be as flat as possible. Accordingly, when the metal reflection layer 26 is formed on the first insulation layer 321, and the second insulation layer 322 is formed on the first insulation layer 321 and covers the metal reflection layer 26, formation of a height difference or a step between the first and second insulation layers 321, 322 can be avoided, thereby further avoiding moisture erosion or metal migration problems about the metal reflection layer 26.

In some embodiments, the upper surface 121 of the epitaxial structure 12 located immediately below the metal reflection layer 26 is flat and continuous, so that the metal reflection layer 26 formed thereon can be as flat as possible.

In some embodiments, a metal adhesion layer may be disposed between the metal reflection layer 26 and the second insulation layer 322. The metal adhesion layer may be made of Ti or Cr, and has a thickness ranging from 0.1 nm to 20 nm, such as from 0.5 nm to 5 nm.

Referring to FIG. 5a, in some embodiment, the first substrate edge region 3010 of the substrate 100 has a first uneven toothed surface which is similar to the first uneven toothed surface 103 shown in FIG. 4a, and the second substrate edge region 3020 has a second uneven toothed surface which is similar to the second uneven toothed surface 104 shown in FIG. 4a, and the second uneven toothed surface has a height greater than a height of the first uneven toothed surface. Accordingly, the first substrate edge region 3010 has a thickness (d1) less than a thickness (d2) of the second substrate edge region 3020. The first substrate edge region 3010 is flatter than the second substrate edge region 3020, so that the adhesion between the insulation layer 32 and the substrate 100 can be facilitated, thereby improving the light-emitting efficiency of the light-emitting device 1, and further improving the manufacturing yield of the light-emitting device 1. Besides, a part of the first semiconductor layer 123 which corresponds in position to the first substrate edge region 3010 can be fully etched, so that a current leakage which may be caused due to incomplete etching of the part of the first semiconductor layer 123 can be prevented.

In this embodiment, the substrate 100 is similar to the substrate 100 shown in FIGS. 3a and 3b, and includes a flat base layer and an uneven toothed structure layer formed on an even surface of the flat base layer. The height of the second uneven toothed surface is equal to that of the uneven toothed structure layer (referring to FIG. 3a) located below the epitaxial structure 12. The height of the second uneven toothed surface may range from 2 μm to 2.5 μm, and the height of the first uneven toothed surface may range from 1 μm to 2 μm.

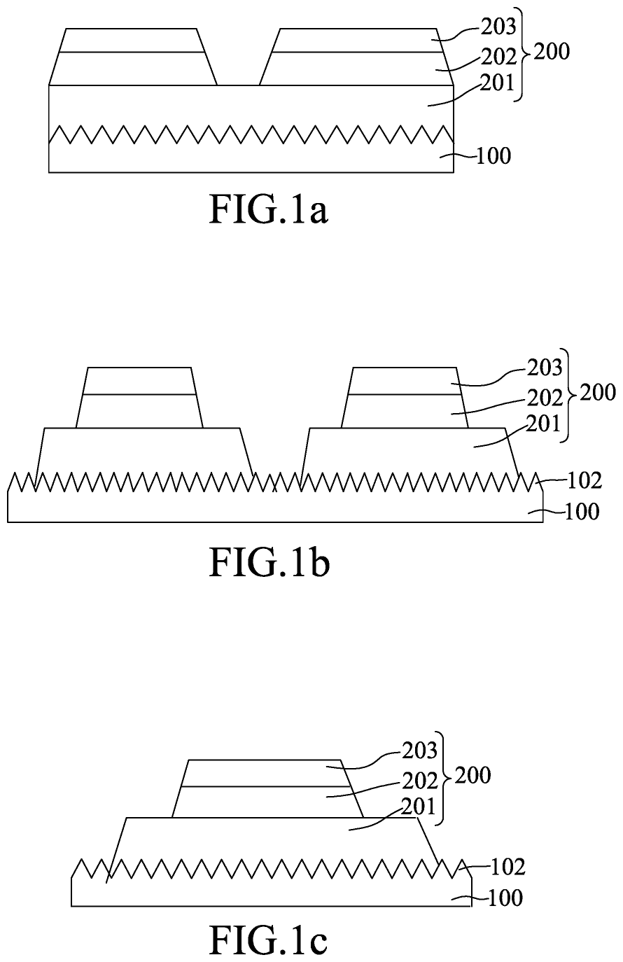

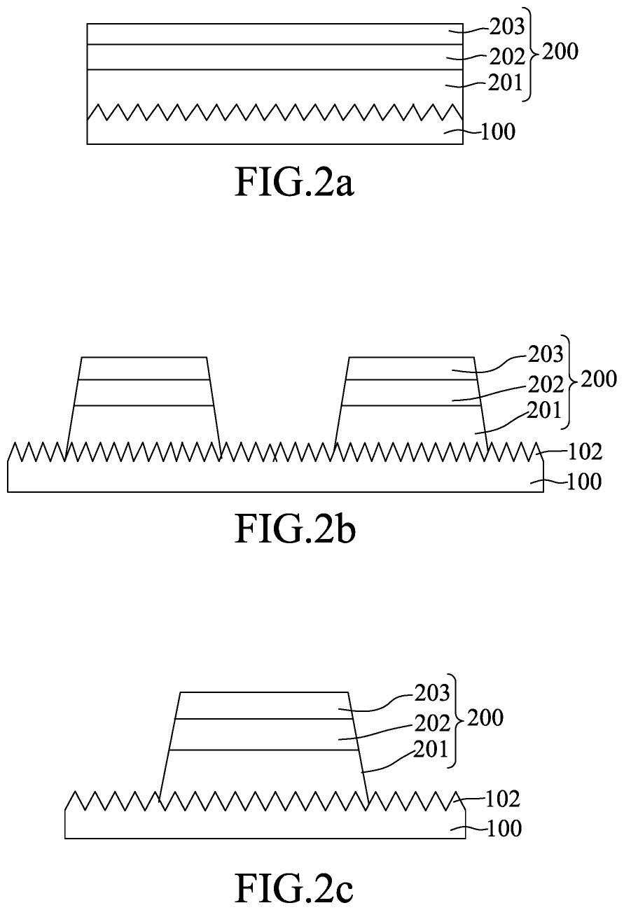

Performance tests are respectively performed on a sample of the light-emitting device shown in FIG. 4a, which is manufactured by the method of the first embodiment, and a sample of the conventional light-emitting device formed by the method shown in FIG. 1b. Results of the tests are shown in the table 1 below.

TABLE 1

| Sample | Voltage | Brightness | Frequency |
|---|---|---|---|
| FIG. 1b | 3.279 | 1145.7 | 454.9 |
| FIG. 4a | 3.252 | 1173.0 | 454.6 |

As can be seen from the results shown in Table 1, the light-emitting device according to the embodiment shown in FIG. 4a has significantly improved voltage and brightness compared to the conventional light-emitting device shown in FIG. 1b. As such, the disclosure is surely advantageous for improving the electrical yield and the light emitting efficiency of the light-emitting device.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for manufacturing a light emitting device, comprising the steps of:
(a) providing a substrate having an upper surface which is patterned, and forming an epitaxial multilayer stack on the upper surface of the substrate, the epitaxial multilayer stack including a first semiconductor layer, an active layer, and a second semiconductor layer which are disposed on the upper surface of the substrate in such order;
(b) etching, from an upper surface of the second semiconductor layer, the second semiconductor layer and the active layer until the first semiconductor layer is exposed so as to form multiple mesa structures, each of which includes a mesa top defined by the upper surface of the second semiconductor layer, a mesa sidewall portion extending downwardly from the mesa top and formed by lateral edge portions of the second semiconductor layer and of the active layer, and a mesa bottom formed by an exposed part of the first semiconductor layer surrounding the mesa sidewall portion; and
(c) etching boundary regions of the mesa structures until the substrate is exposed so as to form dicing line regions on the substrate, each of the boundary regions of the mesa structures including a first boundary region formed by the mesa bottom, and a second boundary region that extends from the mesa top to a bottom surface of the first semiconductor layer and that includes the mesa sidewall portion and a portion of the first semiconductor layer located beneath the mesa sidewall portion and adjoining the mesa bottom, the dicing line regions being formed after the first and second boundary regions of the mesa structures are etched and removed from the substrate.

2. The method as claimed in claim 1, wherein, in the step (c), the first and second boundary regions of the mesa structures are simultaneously etched until the substrate is exposed, each of the dicing line regions being situated between two adjacent ones of the mesa structures, and including a first dicing line region, and two second dicing line regions on two opposite sides of the first dicing line region, the first dicing line region being formed on an exposed part of the substrate from which the first boundary regions of two adjacent ones of the mesa structures are removed, the second dicing line regions being respectively formed on other exposed parts of the substrate from which the second boundary regions of two adjacent ones of the mesa structures are removed, the other exposed parts of the substrate where the second dicing line regions are formed having a thickness greater than a thickness of the exposed part of the substrate where the first dicing line region is formed.

3. The method as claimed in claim 1, wherein, the substrate is a patterned substrate, and includes a flat base layer and an uneven toothed structure layer which is formed on an even surface of the flat base layer and which includes a plurality of protrusions spaced apart from each other.

4. The method as claimed in claim 3, wherein, in the step (c), the first boundary region and the second boundary regions of the mesa structures are simultaneously etched until the substrate is exposed, each of the dicing line regions being situated between two adjacent ones of the mesa structures, and including a first dicing line region, and two second dicing line regions on two opposite sides of the first dicing line region, an exposed part of the substrate, from which the first boundary regions of two adjacent ones of the mesa structures are removed, having an even flat surface on which the first dicing line region is formed, other exposed parts of the substrate from which the second boundary regions of two adjacent ones of the mesa structures are removed having uneven toothed surfaces, each of the other exposed parts of the substrate having a second dicing line region formed thereon.

5. The method as claimed in claim 3, wherein, in the step (c), the first and second boundary regions of the mesa structures are simultaneously etched such that an exposed part of the substrate from which the first boundary regions of two adjacent ones of the mesa structures are removed is formed with a first uneven toothed surface, and other exposed parts of the substrate, from which the second boundary regions of two adjacent ones of the mesa structures are removed, are respectively formed with second uneven toothed surfaces, the exposed part of the substrate where the first uneven toothed surface is formed having a first dicing line region thereon, the other exposed parts of the substrate where the second uneven toothed surfaces are formed having second dicing line regions thereon, the first uneven toothed surface having a height lower than a height of the second uneven toothed surfaces.

6. A light-emitting device, comprising:
a substrate; and
an epitaxial structure formed on an upper surface of the substrate, the epitaxial structure including a first semiconductor layer, an active layer, and a second semiconductor layer which are disposed on the upper surface of the substrate in such order;
the substrate having a substrate edge region surrounding and exposed from the epitaxial structure, the substrate edge region including a first substrate edge region and a second substrate edge region which is more proximate to the epitaxial structure than the first substrate edge region;
the first substrate edge region having a first uneven toothed surface or an even flat surface, the second substrate edge region having a second uneven toothed surface which has a height greater than a height of the first uneven toothed surface, or the even flat surface.

7. The light-emitting device as claimed in claim 6, wherein the height of the first uneven toothed surface is not greater than 2 μm.

8. The light-emitting device as claimed in claim 6, wherein the height of the second uneven toothed surface is not greater than 2 μm.

9. The light-emitting device as claimed in claim 6, wherein the epitaxial structure has a boundary sidewall (B) which extends downward continuously from the second semiconductor layer and has a bottom end meeting the substrate edge region, and wherein no step is formed on at least a portion of the boundary sidewall of the epitaxial structure.

10. The light-emitting device as claimed in claim 6, wherein the epitaxial structure has a boundary sidewall which extends downward continuously from the second semiconductor layer and has a bottom end meeting the substrate edge region, and wherein no step is formed on all part of the boundary sidewall of the epitaxial structure, the second substrate edge region surrounding the epitaxial structure, and the first substrate edge region surrounding the second substrate edge region.

11. The light-emitting device as claimed in claim 6, wherein the epitaxial structure has a boundary side wall which extends downward continuously from the second semiconductor layer and has a bottom end meeting the substrate edge region, and wherein no step is formed on a portion of the boundary sidewall of the epitaxial structure while a step is formed on a remaining portion of the boundary sidewall of the epitaxial structure other than the portion of the boundary sidewall, the step being provided for forming an electrode.

12. The light-emitting device as claimed in claim 6, further comprising an insulation layer which covers the substrate edge region, each of the first and second uneven toothed surfaces including a plurality of protrusions which have a pointed cone-shape, and each of the protrusions of the first uneven toothed surface or the second uneven toothed surface having an arcuate side wall.

13. The light-emitting device as claimed in claim 6, wherein the substrate edge region of the substrate has a width ranging from 4 μm to 20 μm.

14. The light-emitting device as claimed in claim 6, wherein a thickness of the substrate in the first substrate edge region is smaller than a thickness of the substrate in the second substrate edge region.

15. The light-emitting device as claimed in claim 6, wherein the first substrate edge region has a width greater than a width of the second substrate edge region.

16. A light-emitting device, comprising:
a substrate; and
an epitaxial structure formed on an upper surface of the substrate, the epitaxial structure including a first semiconductor layer, an active layer, and a second semiconductor layer which are disposed on the upper surface of the substrate in such order;
wherein the substrate has a substrate edge region surrounding and exposed from the epitaxial structure, the substrate edge region including a first substrate edge region and a second substrate edge region which is more proximate to the epitaxial structure than the first substrate edge region;
a thickness of the substrate in the first substrate edge region is smaller than a thickness of the substrate in the second substrate edge region.

17. The light-emitting device as claimed in claim 16, wherein a part of the substrate in the first substrate edge region is formed with a first uneven toothed surface, and a part of the substrate in the second substrate edge region is formed with a second uneven toothed surface which has a height greater than a height of the first uneven toothed surface.

18. The light-emitting device as claimed in claim 16, wherein a part of the substrate in the first substrate edge region has an even flat surface, and a part of the substrate in the second substrate edge region has a second uneven toothed surface.

19. The light-emitting device as claimed in claim 16, further comprising an insulation layer which covers the substrate edge region.

20. The light-emitting device as claimed in claim 16, wherein the first substrate edge region has a width greater than a width of the second substrate edge region.
